(19) United States
(12) Patent Application Publication
(10) Pub. No.: US 2012/0298187 A1
(43) Pub. Date: Nov. 29, 2012

(54) PHOTOELECTRIC CONVERSION MODULE

(76) Inventors: Hyun-Chul Kim, Yongin-si (KR); Jong-Ki Lee, Yongin-si (KR)

(21) Appl. No.: 13/405,528

(22) Filed: Feb. 27, 2012

Related U.S. Application Data
(60) Provisional application No. 61/489,105, filed on May 23, 2011.

(51) Int. Cl. H01L 31/048; H01L 31/042; H01L 31/18

(52) U.S. Cl. 136/251; 438/64; 136/244; 257/E31.124

(57) ABSTRACT

A photoelectric conversion module includes a first photoelectric cell, a second photoelectric cell, the second photoelectric cell being adjacent to the first photoelectric cell, a first electrode, the first electrode corresponding to the first photoelectric cell, a second electrode, and a connecting member disposed between the first photoelectric cell and the second photoelectric cell, the connecting member electrically connecting the first electrode and the second electrode to each other, the connecting member including a first conductive bump, a second conductive bump, and a conductive connector part contacting the first and second conductive bumps.

### CROSS-REFERENCE TO RELATED APPLICATION

The present application claims priority under 35 U.S.C. § 119(e) to U.S. Provisional Application No. 61/489,105, filed on May 23, 2011, and entitled: “Photoelectric Conversion Module,” which is incorporated herein by reference in its entirety.

### BACKGROUND

1. Field

Embodiments relate to a photoelectric conversion module.

2. Description of the Related Art

Research has been conducted with respect to photoelectric transformation elements that convert light energy to electric energy as energy sources for replacing fossil fuels. A solar cell using sunlight is being focused on.

### SUMMARY

An embodiment is directed to a photoelectric conversion module, including a first photoelectric cell, a second photoelectric cell, the second photoelectric cell being adjacent to the first photoelectric cell, a first electrode, the first electrode corresponding to the first photoelectric cell, a second electrode, and a connecting member disposed between the first photoelectric cell and the second photoelectric cell, the connecting member electrically connecting the first electrode and the second electrode to each other, the connecting member including a first conductive bump, a second conductive bump, and a conductive connector part contacting the first and second conductive bumps.

The conductive connector part may be disposed between the first conductive bump and the second conductive bump, the conductive connector part having concave portions that at least partially surround side surfaces of the first and second conductive bumps at ends thereof.

Ends of the first and second conductive bumps may be aligned above one another, and the conductive connector part may contact the ends of the first and second conductive bumps.

The first and second conductive bumps may be rigid, and the conductive connector part may be flexible.

The conductive connector part may be a hardened compliant material.

The module may further include a first sealing member, the first sealing member being disposed between the first photoelectric cell and the connecting member.

The module may further include a first substrate and a second substrate. The first electrode may be on the first substrate, the second electrode may be on the second substrate, and the first and second electrodes may be between the first and second substrates, and the first sealing member may extend between the first substrate and the second substrate.

The first sealing member may includes an adhering part and a spacer part, the spacer part extending from one of the first and second substrates towards the other of the first and second substrates and defining a distance between the first substrate and the second substrate, the adhering part adhering an end of the spacer part to the other of the first and second substrates.

The spacer part may be tapered at a first end thereof, the first end of the spacer part being adhered to the other of the first and second substrates by the adhering part.

The adhering part may be disposed between the spacer part and the connecting member.

The spacer part may be a glass frit, and the adhering part may be a light-cured adhesive resin.

The first photoelectric cell may be adjacent to the second photoelectric cell, and the first sealing member maybe disposed between the first photoelectric cell and the second photoelectric cell. The module may further include a second sealing member, the second sealing member being disposed between the first photoelectric cell and the connecting member.

The first sealing member may include a first spacer part, the first spacer part being tapered, the second sealing member may include a second spacer part, the second spacer part being tapered, and the first spacer part may be tapered in a direction opposite to that of the second spacer part.

The first electrode may extend from the first photoelectric cell to the connecting member, the second electrode may extend from the second photoelectric cell to the connecting member, and the first and second photoelectric cells may be electrically connected in series.

Another embodiment is directed to a photoelectric conversion module, including a first photoelectric cell, a second photoelectric cell, a first electrode, the first electrode corresponding to the first photoelectric cell, a second electrode, a connecting member disposed between the first photoelectric cell and the second photoelectric cell, the connecting member electrically connecting the first electrode and the second electrode to each other, and a first sealing member, the first sealing member being disposed between the first photoelectric cell and the connecting member, the first sealing member including an adhering part and a spacer part, the spacer part being tapered at a first end thereof.

The first photoelectric cell may be adjacent to the second photoelectric cell, and the first sealing member may be disposed between the first photoelectric cell and the second photoelectric cell. The module may further include a second sealing member, the second sealing member being disposed between the first photoelectric cell and the connecting member.

The first sealing member may include a first spacer part, the first spacer part being tapered, the second sealing member may include a second spacer part, the second spacer part being tapered, and the first spacer part may be tapered in a direction opposite to that of the second spacer part.

Another embodiment is directed to a method of forming a photoelectric conversion module, the method including forming a first conductive bump and a first sealing member part on a first substrate, forming a second conductive bump and a second sealing member part on a second substrate, arranging the first substrate and the second substrate to face each other, such that the first conductive bump is aligned with the second conductive bump, and the first sealing member part is aligned with the second sealing member part, and pressing the first and second substrates together such that the first conductive bump and the second conductive bumps are joined to each other by a conductive connector part disposed therebetween, and, at the same time, the first sealing member part is joined to the second sealing member part.

The first and second substrates may be pressed together so as to deform the conductive connector part, the conductive connector part being deformed so as to form concave portions therein that at least partially surround side surfaces of the first and second conductive bumps at ends thereof.

The first sealing member part may be a spacer part, the spacer part being tapered at a first end thereof, the first end facing the second substrate, and the second sealing member part may be an adhering part.

### BRIEF DESCRIPTION OF THE DRAWINGS

The above and other features and advantages will become more apparent to those of skill in the art by describing in detail example embodiments with reference to the attached drawings, in which:

FIG. 1 illustrates a plan view of a photoelectric conversion module according to an example embodiment;

FIG. 2 illustrates a sectional view of FIG. 1, taken along a line II-II of FIG. 1;

FIG. 3 illustrates a sectional view of FIG. 2, showing a portion of the structure shown in FIG. 2;

FIGS. 4A through 4C illustrate sectional views of stages in a method of fabricating a photoelectric conversion module according to an example embodiment;

FIG. 5 illustrates a sectional view of a photoelectric conversion module according to another example embodiment;

FIG. 6 illustrates a sectional view of a portion of the structure shown in FIG. 5;

FIG. 7 illustrates a sectional view of a photoelectric conversion module according to another example embodiment; and

FIG. 8 illustrates a sectional view of a portion of the structure shown in FIG. 7.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

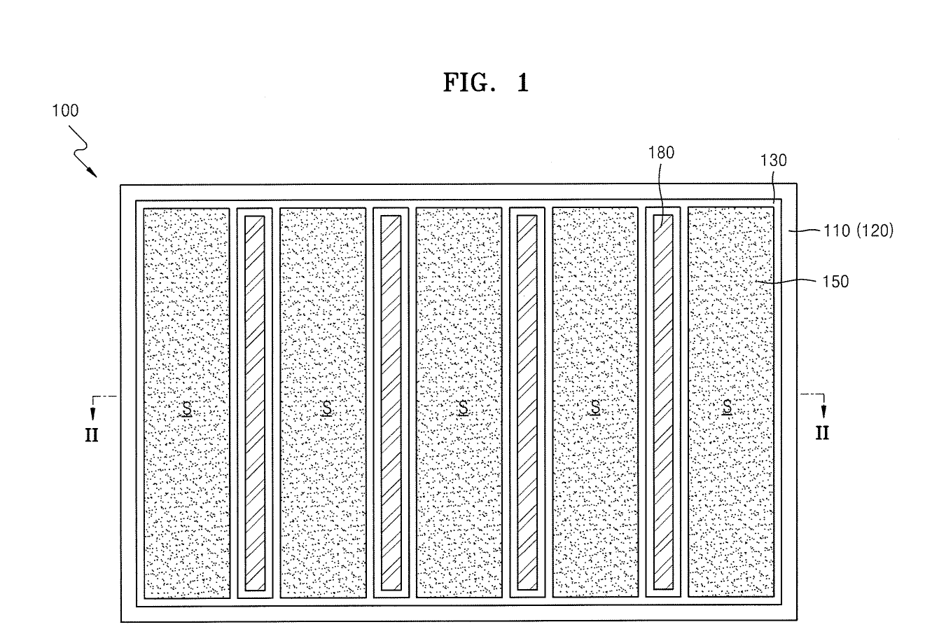

FIG. 1 illustrates a plan view of a photoelectric conversion module 100 according to an example embodiment. In the example shown in FIG. 1, the photoelectric conversion module 100 includes a plurality of photoelectric cells S. A sealing member 130 is arranged between the photoelectric cells S adjacent to each other to define the photoelectric cells S.

A connecting member 180 may be arranged between adjacent sealing members 130. The connecting member 180 may serve to electrically modularize the plurality of photoelectric cells S by electrically interconnecting the photoelectric cells S adjacent to each other. For example, each of the photoelectric cells S may form a series connection or a parallel connection with the adjacent photoelectric cells S via the connecting members 180, and the plurality of photoelectric cells S may be physically supported between a first substrate 110 and a second substrate 120, and thus the plurality of photoelectric cells S may be modularized.

The photoelectric cell S may be filled with electrolyte 150, and the electrolyte 150 filling inside of the photoelectric cell S may be sealed by the sealing members 130 arranged around each of the photoelectric cells S. The sealing members 130 may be formed around the photoelectric cells S to surround the electrolyte 150 and seal the photoelectric cells S to prevent the electrolyte 150 from being leaked to outside.

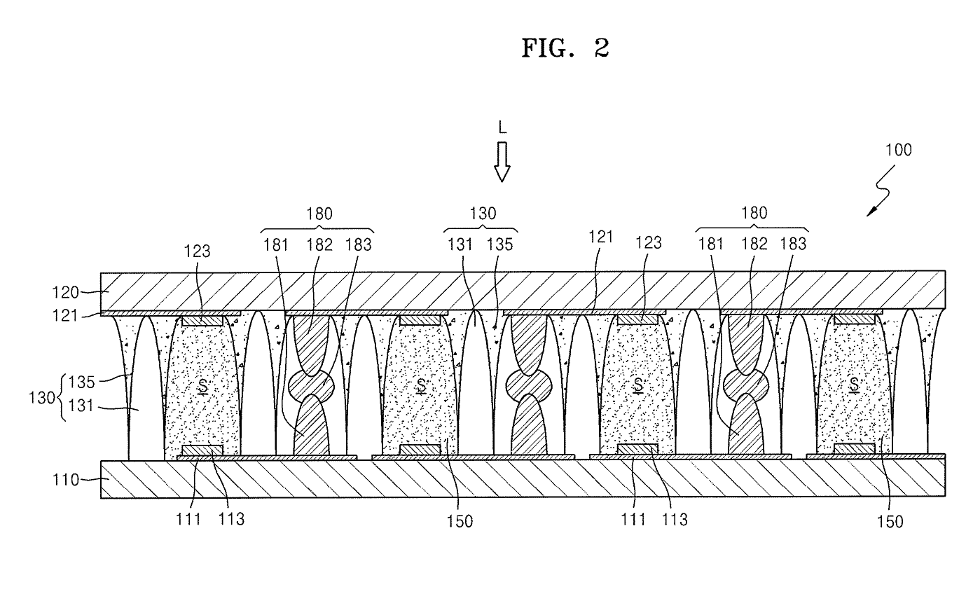

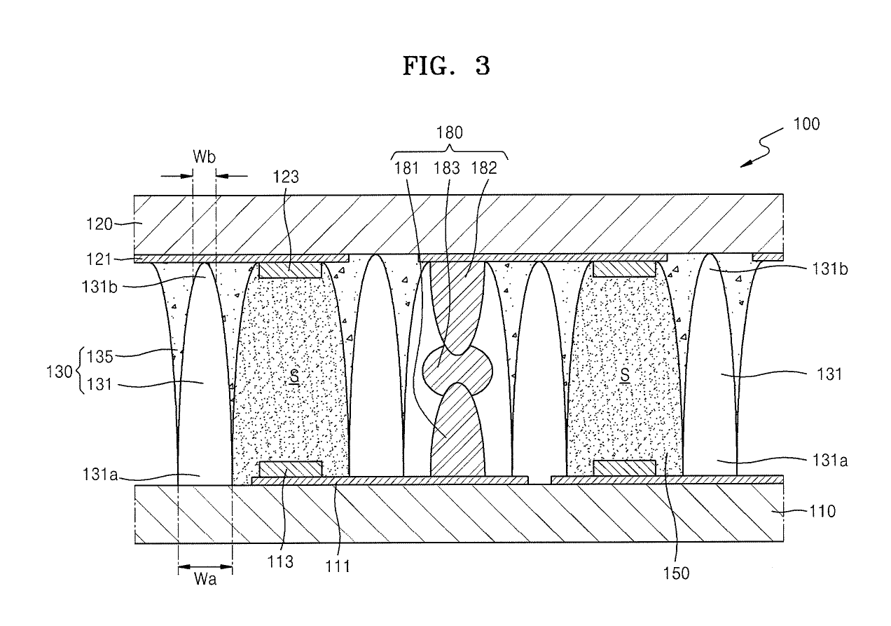

FIG. 2 illustrates a sectional view of FIG. 1, taken along a line II-II of FIG. 1. FIG. 3 illustrates a sectional view of FIG. 2, showing a portion of the structure of FIG. 2 in closer detail. In the example shown in FIG. 2, the photoelectric conversion module 100 includes the first substrate 110 and the second substrate 120 that are arranged to face each other, and the plurality of photoelectric cells S that are defined by the sealing members 130 are formed between the two substrates 110 and 120. The connecting members 180 may be arranged between photoelectric cells S that are adjacent to each other, and may interconnect the photoelectric cells S. For example, the connecting members 180 may interconnect the photoelectric cells S in series.

Referring to FIG. 3, the sealing member 130 formed between the first substrate 110 and the second substrate 120 may define the plurality of photoelectric cells S that are 2-dimensionally arranged between the first substrate 110 and the second substrate 120. Furthermore, the sealing member 130 may surround the electrolyte 150 injected into the photoelectric cells S, and may seal the electrolyte 150. The connecting member 180 for electrically interconnecting the photoelectric cells S may be arranged close to the sealing member 130. For example, the connecting member 180 may be formed between sealing members 130 that are adjacent to each other.

The connecting members 180 may extend vertically to contact a first electrode 111 and a second electrode 121 that are respectively arranged above and below the connecting member 180. The connecting member 180, and the first electrode 111 and the second electrode 121 contacted thereby, may form a connection between adjacent photoelectric cells S so as to interconnect the photoelectric cells S, e.g., in series. For example, referring to FIG. 2, the left-most sealing member 180 in FIG. 2 contacts a first electrode 111, connected to a left-hand photoelectric cell S, and contacts a second electrode 121, connected to a right-hand photoelectric cell S, so as to electrically connect the left and right-hand photoelectric cells S in series.

The connecting member 180 may include conductive bumps 181 and 182 (formed on the first and second substrates 110 and 120, respectively) and a soft conductor layer 183 interconnecting the conductive bumps 181 and 182. The first and second conductive bumps 181 and 182 may be formed on the first and second electrodes 111 and 121 of the first and second substrates 110 and 120, respectively. The conductive bumps 181 and 182 may be formed of a metal with excellent electric conductivity, e.g., silver (Ag). The first conductive bump 181 may be based on the first substrate 110 and may be formed to protrude toward the second substrate 120. The first conductive bump 181 may be pattern-formed on the first substrate 110 through a suitable patterning operation. The second conductive bump 182 may be based on the second substrate 120 and may be formed to protrude toward the first substrate 110. The second conductive bump 182 may be pattern-formed on the second substrate 120 through a suitable patterning operation.

The first and second conductive bumps 181 and 182 (which are formed to protrude toward each other) may be electrically connected to each other by interposing the soft conductor layer 183 therebetween. The first substrate 110, having formed thereon the first conductive bump 181, and the second substrate, having formed thereon the second conductive bump 182, may be pressed toward each other, and the first and second conductive bumps 181 and 182 may be electrically connected to each other by interposing the soft conductor layer 183 therebetween.

The soft conductor layer 183 may serve as a conductive connector part interposed between the first and second conductive bumps 181 and 182, and may form a firm conductive combination by being flexibly deformed between the first and second conductive bumps 181 and 182 according to a pressure for pressing the first substrate 110 and the second substrate 120 toward each other. The soft conductor layer 183 may accommodate the first and second conductive bumps 181 and 182, and may be closely attached to the first and second conductive bumps 181 and 182.

A plurality of first conductive bumps 181 may be formed on the first substrate 110, and a plurality of second conductive bumps 182 may be formed on the second substrate 120 facing the first substrate 110 in correspondence to the locations of the first conductive bumps 181. The first and second conductive bumps 181 and 182 may thus form electrical connections with respect to each other at a plurality of locations.

The plurality of first and second conductive bumps 181 and 182 may have height deviations to some degree in practice, e.g., due to errors in operations for fabricating the same. In this case, if a solid conductor layer having a structural stiffness were used to interconnect first and second conductive bumps 181 and 182, defective connections may occur at multiple locations. In contrast, in the embodiment shown in FIG. 3, firm electrical connections between the first and second conductive bumps 181 and 182 may be formed at multiple locations by using the soft conductor layer 183 which may be flexibly deformed. The soft conductor layer 183 may accommodate height deviations of the first and second conductive bumps 181 and 182, and may be firmly attached to the first and second conductive bumps 181 and 182 to interconnect the first and second conductive bumps 181 and 182.

The soft conductor layer 183 may be formed of a material that is flexible before hardening. The soft conductor layer 183 may be compliant and have temporary flexibility, during formation of the photoelectric conversion module 100, and may then be hardened when the photoelectric conversion module 100 is completed. According to another embodiment, the soft conductor layer 183 may have flexibility during formation of the photoelectric conversion module 100 and may permanently maintain the flexibility even after the photoelectric conversion module 100 is completed.

The soft conductor layer 183 may contain silver (Ag). In an implementation, Ag and a volatile vehicle may be mixed with each other in the soft conductor layer 183. Thus, the soft conductor layer 183 may have sufficient flexibility to accommodate the first and second conductive bumps 181 and 182 according to a pressure for pressing the first and second conductive bumps 181 and 182 toward each other. After the first and second conductive bumps 181 and 182 are connected to each other via the soft conductor layer 183, the soft conductor layer 183 may be hardened through a suitable hardening operation. Raw materials for forming the soft conductor layer 183 may contain highly conductive materials other than Ag, and a vehicle material or other functional materials may be mixed therewith.

The soft conductor layer 183 may be hardened through a suitable hardening operation selected according to characteristics of the raw material. For example, the soft conductor layer 183 may be hardened thermally and/or optically. In an implementation, the soft conductor layer 183 may be heated to remove a volatile vehicle therefrom and to harden the soft conductor layer 183.

The sealing members 130 (which are formed at two opposite sides of the connecting member 180 and define the photoelectric cells S adjacent to each other) may include a spacer part 131 and a sealant 135 serving as an adhering part. The sealant 135 may be formed to surround at least a portion of the spacer part 131.

The spacer part 131 may maintain a constant gap between the first and second substrates 110 and 120. The spacer part 131 may extend to contact each of the first and second substrates 110 and 120. Cell gaps between the photoelectric cells S (2-dimensionally arranged between the first and second substrate 110 and 120) may be controlled by using height of the spacer part 131. The spacer part 131 may be formed of, e.g., glass frit, and fine cell gap may be easily controlled by adjusting an applied thickness of the glass frit.

In an implementation, the spacer part 131 may be formed on the first substrate 110 to protrude from the first substrate 110 toward the second substrate 120. For example, the spacer part 131 may be formed on the first electrode 111 of the first substrate 110. The spacer part 131 may be formed on the first substrate 110 through a series of operations including, e.g., formation of a pattern, drying, and other predetermined operations. For example, the spacer part 131 may be formed of glass frit by applying frit paste on the first substrate 110 then hardening the frit paste by drying and baking the fit paste, and may be patterned on the first substrate 110 by using any of various patterning operations including pattern printing, inkjet printing, a dispenser, a coater, gravure roll application, etc.

The spacer part 131 may have a base end portion 131a, formed at the side of the first substrate 110, and a protruding end portion 131b, which protrudes toward the second substrate 120 from the base end portion 131a. For example, the spacer part 131 may be formed by hardening glass frit paste applied onto the first substrate 110, where the base end portion 131a at the side of the first substrate 110 may be formed to have a greater width than that of the protruding end portion 131b at the side of the second substrate 120. Thus, a width Wa of the base end portion 131a and the width Wb of the protruding end portion 131b (see FIG. 3) may have a relationship of Wa>Wb.

The protruding end portion 131b of the spacer part 131 may be formed to contact the second substrate 120, e.g., by contacting the second electrode 121 of the second substrate 120. The sealant 135 may be applied at least to the protruding end portion 131b of the spacer part 131 to seal the electrolyte 150 and attach the protruding end portion 131b of the spacer part 131 to the second substrate 120 in an airtight manner. The sealant 135 may be applied to the protruding end portion 131b of the spacer part 131 in a large width, such that the sealing member 130 and the second substrate 120 are adhered to each other by way of the sealant 135 at a larger area.

The sealant 135 may be formed of a resin-based material, e.g., a hardening resin which is hardened thermally and/or optically. For example, the sealant 135 may be formed of a UV-hardening material. In an implementation, the sealant 135 may be hardened at a low temperature by irradiating a UV ray to the sealant 135 and heating the sealant 135 at a low temperature, so that other functional layers constituting the photoelectric conversion module 100 may be prevented from being deteriorated at a high temperature.

The sealant 135 may be applied to a location on the second substrate 120 corresponding to the spacer part 131, and may cover and surround at least the protruding end portion 131b of the spacer part 131 while the first and second substrates 110 and 120 are pressed to each other. In an operation for pressing the first and second substrates 110 and 120 to each other, the sealant 135 may be hardened through a suitable hardening operation, such as thermal hardening and/or optical hardening, and may seal a gap between the second substrate 120 and the protruding end portion 131b of the spacer part 131 airtight.

The sealant 135 may be formed not only on the protruding end portion 131b of the spacer part 131, but also on the base end portion 131a of the spacer part 131. For example, the sealant 135 may be formed to completely surround the spacer part 131. When the sealant 135 is formed to completely cover the spacer part 131, adhesiveness between the spacer part 131 and the sealant 135 may be improved. For example, sealing characteristics of the photoelectric cells S may be improved by adhering the inorganic spacer part 131 and the organic sealant 135 to each other airtight.

In the present example embodiment, the first electrode 111 and the second electrode 121 are respectively formed on the first substrate 110 and the second substrate 120. The first substrate 110 and the second substrate 120 may be pressed to each other while interposing the spacer part 131 therebetween, and may be held with a predetermined gap between each other. The second substrate 120 may become a light receiving surface substrate which receives light L (see FIG. 2) and the second electrode 121 may function as a photo electrode. The first substrate 110 may become a counter substrate and the first electrode 111 may function as a counter electrode.

Referring to FIG. 2, a semiconductor layer 123 (to which a photosensitive dye excited by the light L may be absorbed) may be formed on the second electrode 121, and the electrolyte 150 may be interposed between the semiconductor layer 123 and the first electrode 111.

The second substrate 120 may be formed of a transparent material, e.g., a material exhibiting high light transmittance. For example, the second substrate 120 may be formed of a glass substrate or a resin film. Since a resin film is generally flexible, a resin film may be suitable for a purpose that requires flexibility.

The second electrode 121 may function as a negative electrode of the photoelectric conversion module 100. In detail, the second electrode 121 may receive electrons generated through photoelectric conversion and provide a current path. The light L incident via the second electrode 121 may act to excite a photosensitive dye absorbed to the semiconductor layer 123. The second electrode 121 may be formed of a transparent conducting oxide (TCO) with electric conductivity and light transparency, such as ITO (tin-doped indium oxide), FTO (fluorine-doped tin oxide), ATO (antimony-doped tin oxide), etc. The second electrode 121 may further include a metal electrode (not shown) formed of a metal with excellent electric conductivity, such as gold (Au), silver (Ag), aluminum (Al), etc. The metal electrode may be introduced to lower electric resistance of the second electrode 121, and may be formed in, e.g., a stripe pattern or a mesh pattern.

The semiconductor layer 123 may be formed of a suitable semiconductor material for forming a photoelectric conversion module, e.g., a metal oxide containing Cd, Zn, In, Pb, Mo, W, Sb, Ti, Ag, Mn, Sn, Zr, Sr, Ga, Si, or Cr. Photoelectric conversion efficiency of the semiconductor layer 123 may be improved by absorbing a photosensitive dye. For example, the semiconductor layer 123 may be formed by applying a paste having distributed therein semiconductor grains with grain radius from about 5 nm to about 1,000 nm on the substrate 120 on which the electrode 121 is formed, and performing a heating operation or a pressurizing operation for applying a predetermined heat or a predetermined pressure thereto.

The photosensitive dye absorbed to the semiconductor layer 123 may absorb the light L which is incident via the second substrate 120, and electrons of the photosensitive dye may be excited from the ground state to an excitation state. The excited electrons may be transferred to the conduction band of the semiconductor layer 123 via the electrical connection between the photosensitive dye and the semiconductor layer 123, pass through the semiconductor layer 123, reach the second electrode 121, and be withdrawn to outside via the second electrode 121, and thus a driving current for driving an external circuit may be formed.

The photosensitive dye absorbed to the semiconductor layer 123 may be formed of molecules which exhibit absorption in visible ray band and rapidly induce electron movement to the semiconductor layer 123 from light excitation state. The photosensitive dye may be in liquid state, half-solid gel state, or solid state. For example, the photosensitive dye absorbed to the semiconductor layer 123 may be a ruthenium-based photosensitive dye. The semiconductor layer 123 with a predetermined photosensitive dye absorbed thereon may be formed by dipping the substrate 120 into a solution containing the photosensitive dye.

The electrolyte 150 may be a redox electrolyte containing a pair of oxidant and reducing agent. The electrolyte 150 may be, e.g., a solid-type electrolyte, a gel-type electrolyte, or a liquid-type electrolyte.

The first substrate 110 (arranged to face the second substrate 120) may or may not be transparent. However, for improved photoelectric conversion efficiency, the first substrate 110 may be formed of a transparent material and may be formed of a same material as the second substrate 120.

The first electrode 111 may function as a positive electrode of the photoelectric conversion module 100. The photosensitive dye absorbed to the semiconductor layer 123 may absorb light and be excited, and excitation-generated electrons may be withdrawn to the outside via the second electrode 121. Meanwhile, the photosensitive dye which has lost electrons may be reduced again by receiving electrons provided due to oxidization of the electrolyte 150, and the oxidized electrolyte 150 may be reduced again by electrons which arrive to the first electrode 111 via an external circuit. Accordingly, a photoelectric conversion process may be completed.

The first electrode 111 may be formed of a transparent conducting oxide (TCO) with electric conductivity and light transparency, such as ITO, FTO, ATO, etc. The first electrode 111 may further include a metal electrode (not shown) formed of a metal with excellent electric conductivity, such as gold (Au), silver (Ag), aluminum (Al), etc. The metal electrode may be introduced to lower electric resistance of the first electrode 111, and may be formed in, e.g., a stripe pattern or a mesh pattern.

A catalyst layer 113 may be formed on the first electrode 111. The catalyst layer 113 may be formed of a material that functions as a reduction catalyst proving electrons, e.g., metals including platinum (Pt), gold (Au), silver (Au), copper (Cu), aluminum (Al), etc., a metal oxide such as a tin oxide, or a carbon-based material such as a graphite.

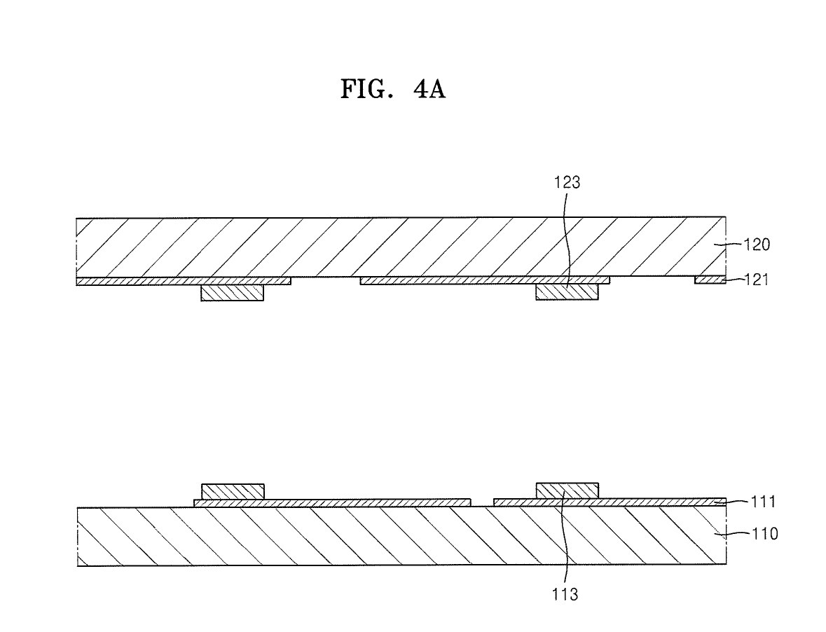

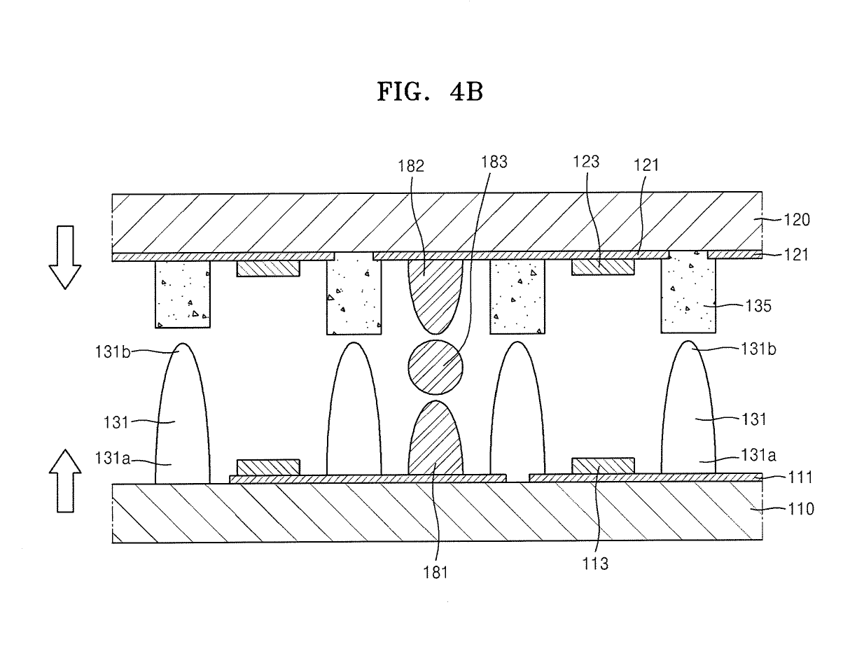

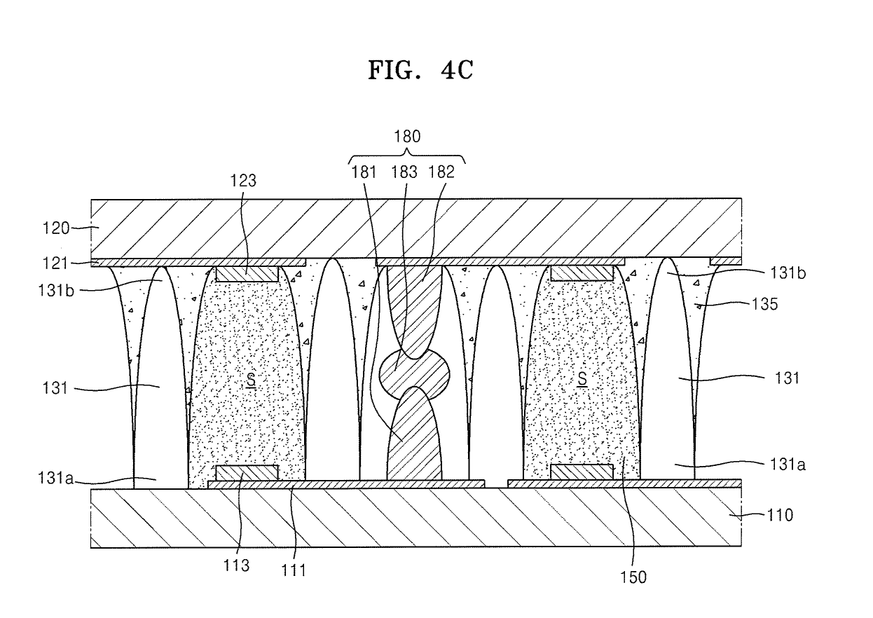

FIGS. 4A through 4C illustrate sectional views of stages in a method of fabricating a photoelectric conversion module according to an example embodiment. First, as shown in FIG. 4A, the first and second substrates 110 and 120 are prepared, and functional layers 111, 113, 121, and 123 for performing photoelectric conversion may be formed on the first and second substrates 110 and 120. The functional layers 111, 113, 121, and 123 may include the semiconductor layer 123 for receiving a light and generating excited electrons, and electrodes 111 and 121 for receiving generated electrons and withdrawing the electrons to outside.

Next, as shown in FIG. 4B, the spacer part 131 may be pattern-formed on the first substrate 110. For example, the spacer part 131 may be formed at boundaries between the photoelectric cells S, and may be formed on the first electrode 111. The spacer part 131 may be formed of, e.g., glass frit.

The spacer part 131 may be formed by forming a predetermined pattern on the first substrate 110 by using any of various patterning operations including pattern printing, inkjet printing, a dispenser, a coater, gravure roll application, etc.

Next, the spacer part 131 pattern-formed on the first substrate 110 may be hardened. For example, the solidified spacer part 131 may be formed by hardening the spacer part 131 through thermal baking or laser irradiation.

Next, the sealant 135 may be formed at a location on the second substrate 120 corresponding to the spacer part 131. For example, a hardening resin for forming the sealant 135 may be pattern-formed on the second electrode 121 of the second substrate 120. The sealant 135 may be applied to form a pattern on the second substrate 120 by using any of various patterning operations including pattern printing, inkjet printing, a dispenser, a coater, gravure roll application, etc.

Next, the first substrate 110 (having formed thereon the spacer part 131) and the second substrate 120 (having applied thereto the sealant 135) may be arranged to face each other and may be pressed toward each other. For example, the first and second substrates 110 and 120 may be pressed to each other until the spacer part 131 of the first substrate 110 contacts the second substrate 120 (or the second electrode 121 of the second substrate 120). The spacer part 131 between the first and second substrates 110 and 120 may form a suitable cell gap. At this point, the sealant 135 formed on the second substrate 120 may be pressed toward the first substrate 110 and may cover at least a portion of the spacer part 131, that is, the protruding end portion 131b, or may completely cover the spacer part 131 including the base end portion 131a.

Next, the sealant 135 may be hardened. For example, the sealant 135 may be hardened through UV light irradiation or low-temperature thermal treatment, and, during the UV hardening and the heat treatment, the first and second substrates 110 and 120 may be flipped over to harden the sealant 135 on the both of the substrates 110 and 120.

Next, the electrolyte 150 may be injected into the photoelectric cells S via injection holes (not shown) formed in the first substrate 110 or the second substrate 120, and thus the photoelectric conversion module as shown in FIG. 4C may be acquired.

In the above example embodiment, the spacer part 131 and the semiconductor layer 123 are formed on the first and second substrates 110 and 120, respectively. In another implementation, if the spacer part 131 and the semiconductor layer 123 are formed on a same substrate, the photosensitive dye may be absorbed to the semiconductor layer 123 after formation of the spacer part 131, that is, pattern-formation of the spacer part 131. For example, the semiconductor layer 123 having absorbed thereto a predetermined photosensitive dye may be acquired by dipping a substrate (having formed thereon the spacer part 131 and the semiconductor layer 123) into a solution containing the photosensitive dye. Next, excessive photosensitive dye attached to the spacer part 131 may be removed by arranging a mask (not shown) having the pattern of the spacer part 131 and passing the spacer part 131 through a plasma cleaner (not shown). After the photosensitive dye on the spacer part 131 is removed, the spacer part 131 and the sealant 135 may be attached to each other, where adhesiveness between the spacer part 131 and the sealant 135 may be improved.

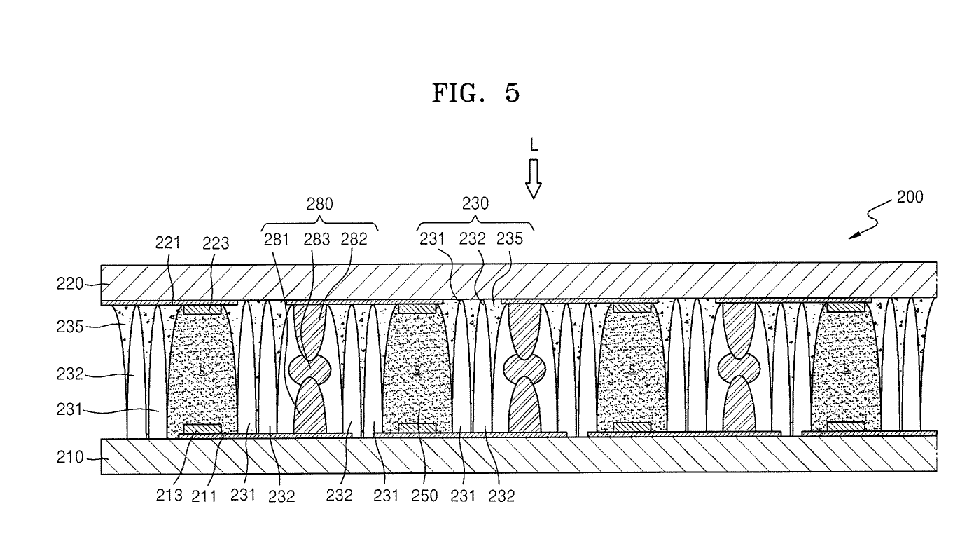

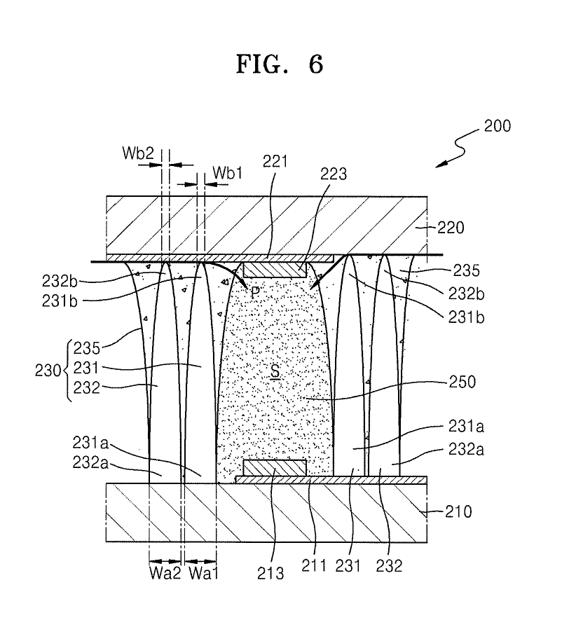

FIG. 5 illustrates a sectional view of a photoelectric conversion module 200 according to another example embodiment. FIG. 6 illustrates a sectional view showing a portion of the structure shown in FIG. 5.

Referring to FIGS. 5 and 6, first and second substrates 210 and 220 may be arranged to face each other, and the plurality of photoelectric cells S may be arranged between the first and second substrates 210 and 220. The photoelectric cells S may be defined by a sealing member 230. A connecting member 280 (for electrically interconnecting the photoelectric cells S adjacent to each other) may be arranged between the sealing member 230 adjacent to each other.

The connecting member 280 includes conductive bumps 281 and 282 formed on the first and second substrates 210 and 220 and protruding toward each other, and a soft conductor 283 interconnecting the conductive bumps 281 and 282, and interposed between the conductive bumps 281 and 282. The first and second conductive bumps 281 and 282 may be formed on first and second electrodes 211 and 221 of the first and second substrates 210 and 220, respectively.

The sealing member 230 may include pairs of first spacer parts 231 and second spacer parts 232 that are substantially symmetrical around the photoelectric cells S. Two first spacer parts 231 may be disposed at two opposite sides of a photoelectric cell S within a relatively small distance. The two second spacer parts 232 may be disposed at two opposite sides of the same photoelectric cell S within a relatively large distance, i.e., the second spacer parts 232 are outboard of the first spacer parts 231 with respect to the photoelectric cell S (see FIG. 6).

The first and second spacer parts 231 and 232 may be formed based on the first substrate 210 and may be pattern-formed on the first substrate 210. For example, the first and second spacer parts 231 and 232 may be formed on the first electrode 211 of the first substrate 210. By forming the first and second spacer parts 231 and 232, an overlapped sealing structure may be formed. For example, electrolyte 250 included in the photoelectric cells S may be sealed by the first and second spacer parts 231 and 232 constituting a double sealing structure. Such a double sealing structure may effectively reduce leakage of the electrolyte 250 and may effectively block permeation of harmful external substances, such as moisture.

When a double sealing structure is formed by the first and second spacer parts 231 and 232 as shown in FIG. 6, double barrier walls are formed on a path P (shown in the upper right portion of FIG. 6) along which harmful external substances, such as moisture, may permeate. Thus, permeation of external substances and leakage of electrolyte may be effectively prevented.

The first and second spacer parts 231 and 232 may have base end portions 231a and 232a, formed at the side of the first substrate 110, and respective protruding end portions 231b and 232b, which protrude toward the second substrate 120 from the base end portions 231a and 232a. The first and second spacer parts 231 and 232 may be formed by hardening glass frit paste applied onto the first substrate 210, where the base end portions 231a and 232b at the side of the first substrate 210 may be formed to have a greater width than that of the protruding end portions 231b and 232b at the side of the second substrate 220. Thus, the widths Wa1 and Wa2 of the base end portions 231a and 232a, and the widths Wb1 and Wb2 of the protruding end portions 231b and 232b, may have a relationship of Wa1, Wa2>Wb1, Wb2.

The protruding end portions 231b and 232b may be formed to contact the second substrate 220 or the second electrode 221 of the second substrate 220. The sealant 235 may be applied to the protruding end portion 231b and 232b of the first and second spacer parts 231 and 232. The sealant 235 may form an airtight attachment between the protruding end portions 231b and 232b and the second substrate 220. In an implementation, the sealant 235 may be formed to completely cover the first spacer part 231 or the second spacer part 232, including the protruding end portions 231b and 232b.

In the embodiment shown in FIG. 6, a double sealing structure is formed by using the first spacer part 231 and the second spacer part 232. However, a photoelectric conversion module according to an embodiment may include three or more spacer parts, e.g., a triple sealing structure or more.

The first electrode 211 and the second electrode 221 may be respectively formed on the first substrate 210 and the second substrate 220. The first substrate 210 and the second substrate 220 may be pressed to each other while interposing the spacer parts 231 and 232 therebetween, and the substrates may be held with a predetermined gap between each other by the spacer parts. The second substrate 220 may serve as a light receiving surface substrate (which receives light L) and the second electrode 221 may function as a photo electrode. The first substrate 210 may serve as a counter substrate and the first electrode 211 may function as a counter electrode.

A semiconductor layer 223, to which a photosensitive dye excited by the light L may be absorbed, may be formed on the second electrode 221. The electrolyte 250 may be interposed between the semiconductor layer 223 and the first electrode 211.

The photosensitive dye absorbed to the semiconductor layer 223 may absorb light L incident via the second substrate 220, and electrons of the photosensitive dye may be excited from the ground state to an excitation state. The excited electrons may be transferred to the conduction band of the semiconductor layer 223 via an electrical connection between the photosensitive dye and the semiconductor layer 223, pass through the semiconductor layer 223, reach the second electrode 221, and be withdrawn to outside via the second electrode 221. Thus, a driving current for driving an external circuit may be formed. A catalyst layer 213 may be formed on the first electrode 211.

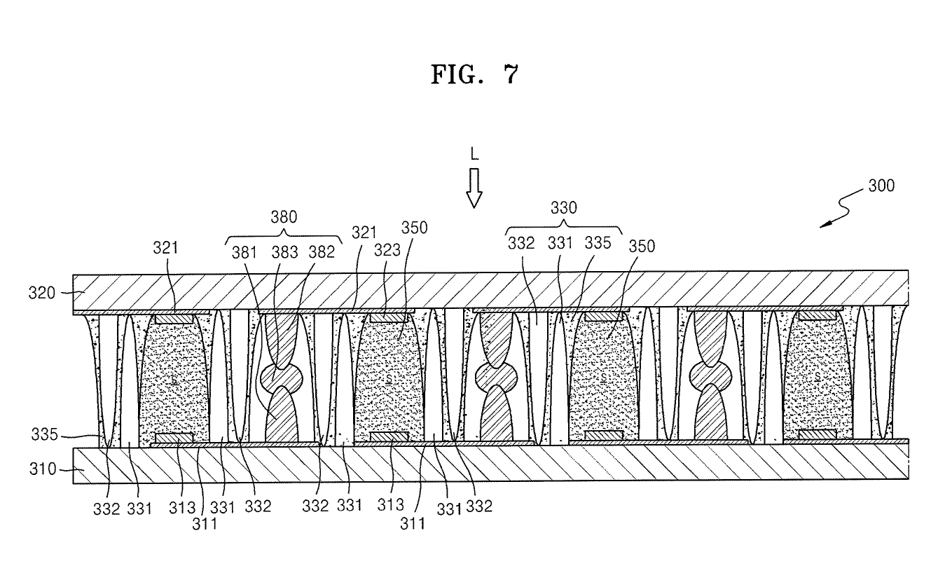

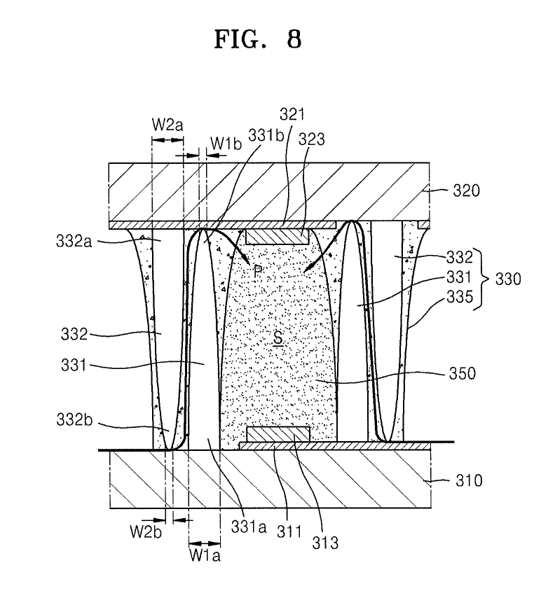

FIG. 7 illustrates a sectional view of a photoelectric conversion module 300 according to another example embodiment. FIG. 8 illustrates a sectional view showing a portion of the structure shown in FIG. 7.

Referring to FIGS. 7 and 8, first and second substrates 310 and 320 may be arranged to face each other, and a plurality of photoelectric cells S may be arranged between the first and second substrates 310 and 320. The photoelectric cells S may be defined by a sealing member 330. A connecting member 380, for electrically interconnecting photoelectric cells S that are adjacent to each other, may be arranged between sealing members 330 that are adjacent to each other.

The connecting member 380 may include conductive bumps 381 and 382 formed on the first and second substrates 310 and 320 and protruding toward each other, and a soft conductor 383, interconnecting the conductive bumps 381 and 382, and interposed between the conductive bumps 381 and 382.

The sealing member 330 may include pairs of first spacer parts 331 and second spacer parts 332 that are substantially symmetrical around the photoelectric cells S. Two first spacer parts 331 may be disposed at two opposite sides of a photoelectric cell S within a relatively small distance, and two second spacer parts 332 may be disposed at two opposite sides of the photoelectric cell S within a relatively large distance, outboard of the first spacer parts 331.

In the present example embodiment, the first and second spacer parts 331 and 332 may be respectively formed based on different substrates 310 and 320. For example, the first spacer part 331 may be formed based on the first substrate 310 and may be pattern-formed on the first substrate 310. The first spacer part 331 may have a protruding end portion 331b protruding toward the second substrate 320 from a base end portion 331a fixed to the first substrate 310. The sealant 335 may be applied to the protruding end portion 331b of the first spacer part 331. The sealant 335 may form an airtight attachment between the protruding end portion 331b and the second substrate 320. The sealant 335 may form an airtight attachment between the protruding end portion 331b and the second electrode 321 of the second substrate 320. In an implementation, the sealant 335 may be formed to completely cover the first spacer part 331, including the protruding end portion 331b.

The second spacer part 332 may have a protruding end portion 332b protruding toward the first substrate 310 from a base end portion 332a fixed to the second substrate 320. The sealant 335 may be applied to the protruding end portion 332b of the second spacer part 332. The sealant 335 may form an airtight attachment between the protruding end portion 332b and the first substrate 310. The sealant 335 may form an airtight attachment between the protruding end portion 332b and the first electrode 311 of the first substrate 310. In an implementation, the sealant 335 may be formed to completely cover the second spacer part 332, including the protruding end portion 332b.

In the embodiment shown in FIG. 8, the first and second spacers 331 and 332 may be formed to be reversed to each other. In other words, the first and second spacer parts 331 and 332 may be formed to be vertically reversed with respect to each other. The spacer parts 331 and 332 may be formed to be reversed with respect to each other to prevent leakage of electrolyte 350 sealed inside the photoelectric cells S and corruption of the electrolyte 350 due to permeation of harmful external substances, such as moisture.

Referring to FIG. 8, the first and second spacer parts 331 and 332 may be fixed to any one of the first and second substrates 310 and 320, and may contact the other one of the first and second substrates 310 and 320.

The electrolyte 350 included in a single photoelectric cells S may leak to the outside via the weakest point of the sealing structure formed by the first and second spacer parts 331 and 332, such as a gap between the protruding end portion 332b of the second spacer part 332 and the first substrate 310 and a gap between the protruding end portion 331b of the first spacer part 331 and the second substrate 320. The second spacer part 332 may be based on the second substrate 320 and may be pattern-formed on the second substrate 320, and thus a base end portion 332b of the second spacer part 332 and the second substrate 320 may be firmly and tightly attached to each other. Furthermore, the first spacer part 331 may be based on the first substrate 310 and may be pattern-formed on the first substrate 310, and thus a base end portion 331b of the first spacer part 331 and the first substrate 310 may be firmly and tightly attached to each other. The base end portions 331a and 332a and the protruding end portions 331b and 332b of the first and second spacer parts 331 and 332 may exhibit different sealing efficiencies. As the first and second spacer parts 331 and 332 are arranged to be vertically reversed with respect to each other, a zigzag permeation path P may be formed, and thus permeation of harmful external substances and leakage of the electrolyte 350 may be effectively reduced. Thus, for a harmful external substance, such as moisture, to permeate into the photoelectric cells S, it may have to follow a virtual permeation path P (see FIG. 8) that includes a gap between the protruding end portion 332b of the second spacer part 332 and the first substrate 310, and a gap between the protruding end portion 331b of the first spacer part 331 and the second substrate 320. A zigzag permeation path P is formed via the first and second spacer parts 331 and 332 that are vertically reversed with respect to each other, and thus length of the permeation path P increases, and thus permeation of harmful external substances, such as moisture, and leakage of the electrolyte 350 may be effectively reduced.

The first electrode 311 and the second electrode 321 may be respectively formed on the first substrate 310 and the second substrate 320, and the first substrate 310 and the second substrate 320 may be pressed to each other while interposing the spacer parts 331 and 332 therebetween. Thus, the substrates may be held with a predetermined gap therebetween by the spacer parts.

The second substrate 320 may serve as a light receiving surface substrate (which receives light L) and the second electrode 321 may function as a photo electrode. The first substrate 310 may serve as a counter substrate and the first electrode 311 may function as a counter electrode.

A semiconductor layer 323, to which a photosensitive dye, excitable by the light L may be absorbed, may be formed on the second electrode 321. The electrolyte 350 may be interposed between the semiconductor layer 323 and the first electrode 311. A catalyst layer 313 may be formed on the first electrode 311.

By way of summation and review, among solar cells having various operation principles, wafer-type silicon or crystalline solar cells using p-n junctions of semiconductors have been popular, but such cells may require high manufacturing costs to form and process high purity semiconductor materials. A dye-sensitized solar cell (including a photosensitive dye that receives incident light with a wavelength of visible rays and generates excited electrons therefrom, a semiconductor material for receiving the excited electrons, and an electrolyte, which reacts with electrons returning from an external circuit) may exhibit significantly higher photoelectric transformation efficiency as compared to other solar cells. Therefore, a dye-sensitized solar cell is well suited to become a next-generation solar cell.

As described above, example embodiments may provide a photoelectric conversion module with improved sealing characteristics. A photoelectric conversion module, in which fine cell gaps may be easily controlled, uniform cell gaps may be formed, and sealing characteristics may be improved, may be provided according to embodiments. Such embodiments may be applied to, e.g., a dye-sensitized solar cell.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoelectric conversion module, comprising:
a first photoelectric cell;
a second photoelectric cell, the second photoelectric cell being adjacent to the first photoelectric cell;
a first electrode, the first electrode corresponding to the first photoelectric cell;
a second electrode; and
a connecting member disposed between the first photoelectric cell and the second photoelectric cell, the connecting member electrically connecting the first electrode and the second electrode to each other, the connecting member including a first conductive bump, a second conductive bump, and a conductive connector part contacting the first and second conductive bumps.

2. The module as claimed in claim 1, wherein the conductive connector part is disposed between the first conductive bump and the second conductive bump, the conductive connector part having concave portions that at least partially surround side surfaces of the first and second conductive bumps at ends thereof.

3. The module as claimed in claim 2, wherein ends of the first and second conductive bumps are aligned above one another, and the conductive connector part contacts the ends of the first and second conductive bumps.

4. The module as claimed in claim 1, wherein:
the first and second conductive bumps are rigid, and
the conductive connector part is flexible.

5. The module as claimed in claim 1, wherein the conductive connector part is a hardened compliant material.

6. The module as claimed in claim 1, further comprising a first sealing member, the first sealing member being disposed between the first photoelectric cell and the connecting member.

7. The module as claimed in claim 6, further comprising:
a first substrate; and
a second substrate, wherein:
the first electrode is on the first substrate, the second electrode is on the second substrate, and the first and second electrodes are between the first and second substrates, and
the first sealing member extends between the first substrate and the second substrate.

8. The module as claimed in claim 7, wherein the first sealing member includes:
an adhering part; and
a spacer part, the spacer part extending from one of the first and second substrates towards the other of the first and second substrates and defining a distance between the first substrate and the second substrate, the adhering part adhering an end of the spacer part to the other of the first and second substrates.

9. The module as claimed in claim 8, wherein the spacer part is tapered at a first end thereof, the first end of the spacer part being adhered to the other of the first and second substrates by the adhering part.

10. The module as claimed in claim 9, wherein the adhering part is disposed between the spacer part and the connecting member.

11. The module as claimed in claim 9, wherein the spacer part is a glass frit, and the adhering part is a light-cured adhesive resin.

12. The module as claimed in claim 6, wherein:
the first photoelectric cell is adjacent to the second photoelectric cell, and
the first sealing member is disposed between the first photoelectric cell and the second photoelectric cell,
the module further comprising a second sealing member, the second sealing member being disposed between the first photoelectric cell and the connecting member.

13. The module as claimed in claim 12, wherein:
the first sealing member includes a first spacer part, the first spacer part being tapered,
the second sealing member includes a second spacer part, the second spacer part being tapered, and
the first spacer part is tapered in a direction opposite to that of the second spacer part.

14. The module as claimed in claim 1, wherein the first electrode extends from the first photoelectric cell to the connecting member, the second electrode extends from the second photoelectric cell to the connecting member, and the first and second photoelectric cells are electrically connected in series.

15. A photoelectric conversion module, comprising:
a first photoelectric cell;
a second photoelectric cell;
a first electrode, the first electrode corresponding to the first photoelectric cell;
a second electrode;
a connecting member disposed between the first photoelectric cell and the second photoelectric cell, the connecting member electrically connecting the first electrode and the second electrode to each other; and
a first sealing member, the first sealing member being disposed between the first photoelectric cell and the connecting member, the first sealing member including an adhering part and a spacer part, the spacer part being tapered at a first end thereof.

16. The module as claimed in claim 15, wherein:
the first photoelectric cell is adjacent to the second photoelectric cell, and
the first sealing member is disposed between the first photoelectric cell and the second photoelectric cell,
the module further comprising a second sealing member, the second sealing member being disposed between the first photoelectric cell and the connecting member.

17. The module as claimed in claim 16, wherein:
the first sealing member includes a first spacer part, the first spacer part being tapered,
the second sealing member includes a second spacer part, the second spacer part being tapered, and
the first spacer part is tapered in a direction opposite to that of the second spacer part.

18. A method of forming a photoelectric conversion module, the method comprising:
forming a first conductive bump and a first sealing member part on a first substrate;
forming a second conductive bump and a second sealing member part on a second substrate;
arranging the first substrate and the second substrate to face each other, such that the first conductive bump is aligned with the second conductive bump, and the first sealing member part is aligned with the second sealing member part; and
pressing the first and second substrates together such that the first conductive bump and the second conductive bumps are joined to each other by a conductive connector part disposed therebetween, and, at the same time, the first sealing member part is joined to the second sealing member part.

19. The method as claimed in claim 18, wherein the first and second substrates are pressed together so as to deform the conductive connector part, the conductive connector part being deformed so as to form concave portions therein that at least partially surround side surfaces of the first and second conductive bumps at ends thereof.

20. The method as claimed in claim 19, wherein:
the first sealing member part is a spacer part, the spacer part being tapered at a first end thereof, the first end facing the second substrate, and
the second sealing member part is an adhering part.
